(19) United States
(12) Patent Application Publication
(10) Pub. No.: US 2023/0209702 A1
(43) Pub. Date: Jun. 29, 2023

(54) SUBSTRATE WARPAGE REDUCTION TECHNIQUES WITH LAMINATE GLASS CLOTH WEAVE

(71) Applicant: Intel Corporation, Santa Clara, CA (US)

(72) Inventors: Satyajit WALWADKAR, Portland, OR (US); Min PEI, Beaverton, OR (US); George HSIEH, Portland, OR (US)

(21) Appl. No.: 17/561,637

(22) Filed: Dec. 23, 2021

(51) Int. Cl. H05K 1/02; H05K 1/11; H05K 1/03; H05K 1/18

(52) U.S. Cl. CPC H05K 1/0271; H05K 1/115; H05K 1/0306; H05K 1/181; H05K 1/038; H05K 2201/068

(57) ABSTRACT

Warpage reduction through laminate glass cloth design modification is described herein. In one example, a substrate for a microelectronic assembly, includes one or more glass-cloth containing layers. At least one of the glass-cloth containing layers includes a glass cloth having a weave including: a first plurality of parallel glass fibers, a second plurality of parallel glass fibers, and a third plurality of parallel glass fibers interwoven with one another in a plane. The second plurality of parallel glass fibers crosses the first plurality of glass fibers at a first angle, and the third plurality of parallel glass fibers crosses the first plurality of glass fibers at a second angle and crosses the second plurality of glass fibers at a third angle. In one example, the glass cloth weave includes a hexagonal pattern.

### FIELD

This disclosure relates generally to semiconductor substrates and packages and some examples relate more particularly to glass-cloth weaves in glass-cloth containing substrates for reduction in substrate warpage.

### BACKGROUND OF THE DISCLOSURE

Microelectronic assemblies and packages can include various substrates for supporting and connecting components, such as a printed circuit boards (PCBs). PCBs are used as substrates for mounting electronic components and provide electrical interconnections between those components and to components external to the PCB. PCBs and other substrates can be susceptible to warpage, especially during manufacturing processes involving the application of heat. Substrate warpage refers to a deformation or other unintentional change in the geometry of the substrate. Substrate warpage can be a source of low yield during semiconductor packaging processes.

### BRIEF DESCRIPTION OF THE DRAWINGS

So that the manner in which the features of the present embodiments can be understood in detail, a more particular description of the embodiments, briefly summarized above, may be had by reference to embodiments, some of which are illustrated in the appended drawings. It is to be noted, however, that the appended drawings illustrate only typical embodiments and are therefore not to be considered limiting of its scope.

FIG. 1 illustrates a block diagram of a cross-section of a printed circuit board (PCB), according to one example.

FIG. 2 illustrates an example of convex warpage and concave warpage.

FIG. 3 illustrates a top-down view of an example of glass cloth with a conventional two-way weave pattern.

FIG. 4A is a cross-sectional view of an example of a glass cloth impregnated with epoxy resin.

FIG. 4B is a close-up cross-sectional view of the glass cloth of FIG. 4A.

FIG. 5 illustrates an example of a portion of glass cloth with a three-way weave pattern.

FIG. 6A is a close-up top-down view of an example of a glass cloth with a tri-axial weave.

FIG. 6B is a close-up top-down view of an example of a glass cloth with a tri-axial weave.

FIG. 7A illustrates an example of glass fibers that are evenly spaced.

FIG. 7B illustrates an example of pairs of closely-spaced glass fibers.

FIG. 8A illustrates an example of a glass cloth with a tetra-axial weave.

FIG. 8B is a close-up top-down view of an example of a glass cloth with two sets of tri-axial weaves.

FIG. 9 is a flow diagram of a method of an example of manufacturing a substrate including glass cloth.

FIG. 10 depicts a compute platform such as a server or similar computing system in which techniques described herein may be implemented.

FIG. 11 illustrates a cross-section side view of an integrated circuit package assembly.

FIG. 12 illustrates a package assembly that includes multiple units of hardware logic chiplets connected to a substrate (e.g., base die).

FIG. 13 illustrates a package assembly including interchangeable chiplets.

### DETAILED DESCRIPTION

Substrate warpage can be reduced by forming a substrate with a glass cloth having a weave as described herein. In one example, a laminate based substrate includes a glass cloth. The glass cloth has a weave including three or more sets of glass fibers interwoven with one another, as described in greater detail below. In one such example, the weave has a trigonal or hexagonal pattern. In one example, the weave pattern of the glass cloth includes at least one set of glass fibers with three-fold symmetry

Warpage in electronic packaging components, such as laminate substrates, is a significant factor that affects product yield during processes such as surface mount technology (SMT) processes. Warpage is the out-of-plane (e.g., normal to the (x,y) board area) deflection. Warpage is typically caused by a mismatch of the coefficient of thermal expansion (CTE) between multiple layers of the substrate. As used herein, a substrate may include: a glass-cloth containing substrate, package substrate, a flip chip ball grid array (FCBGA) package, a printed circuit board (PCB), a motherboard, an interposer, a redistribution layer (RDL), or other laminate type substrate.

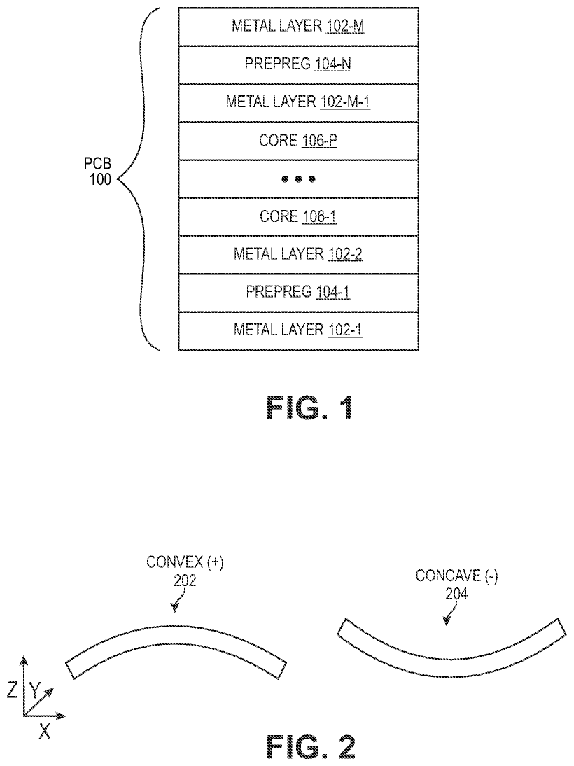

For example, warpage can occur when there are mismatched CTEs between layers of a printed circuit board (PCB). FIG. 1 illustrates a block diagram of a cross-section of a printed circuit board (PCB), according to one example. In the example illustrated in FIG. 1, the PCB 100 includes M layers of metal, N layers of prepreg, and P layers of core. The metal layers 102-1-102-M are alternated with the prepreg and core layers. For example, the metal layers 102-2 and 102-M−1 are each between a prepreg and core layer. The PCB 100 also includes a metal layer 102-1 as a bottom layer of the PCB and a metal layer 102-M as a top layer of the PCB. The metal layers 102-1-102-M may include patterned layers of copper or other metal.

In one example, the prepreg layers 104-1-104-N and the core layers 106-1-106-P each include a glass cloth impregnated with an epoxy. Glass cloth (which can also be referred to as glass fabric) is a material made from bundles of glass filaments woven together. Glass filaments are fine strands of glass (e.g., silica-based glass or other glass). In one example, glass filaments can be formed by extruding glass into long fibers with a small diameter. For example, glass filaments may have a diameter in a range of 4-9 μm. Other Examples of glass cloth may include glass filaments having a diameter that is less than 4 um or greater than 9 μm. The glass filaments can then be bundled together and the bundles of glass filaments are woven together to form a cloth or fabric. A bundle or set of glass filaments may also be referred to as a fiber in a glass cloth (e.g., a fiber of a glass cloth includes a plurality of glass filaments). In one example, the glass cloth is then impregnated with an epoxy.

In one example, the difference between the prepreg layers 104-1-104-N and the core layers 106-1-106-P is that the core layers 106-1-106-P have undergone heat treatments to cure (e.g., fully cure) the epoxy, whereas the epoxy in the prepreg layers 104-1-104-N is not fully cured (e.g., B-stage epoxy). Thus, the core layers 106-1-106-P are typically harder than the prepreg layers 104-1-104-N. Typically, the core provides structural rigidity and electrical isolation between copper layers, and the prepreg material provides an insulative and adhesive layer between copper layers. In one example, the core layers 106-1-106-P are coated or bonded with copper on one or both surfaces. In one example, the layers 102-1-102-M, 104-1-104N, and 106-1-106P are vertically stacked and laminated to form the PCB 100.

As mentioned above, warpage can develop during the manufacturing process and continue to evolve during the substrate assembly process. As a result, warpage effects are prevalent both at room and elevated temperature and typically present as either a convex or concave shape, as shown in FIG. 2. However, in some cases, warpage can present as complex shapes. FIG. 2 illustrates an example of convex warpage 202 and concave warpage 204, which may affect one or more layers of a substrate. While there are no direct means to eliminate warpage, some commonly adopted industry methods rely on using external sources such as using constraints with the help of fixtures and pallets during SMT reflow assembly to control the substrate or PCB warpage.

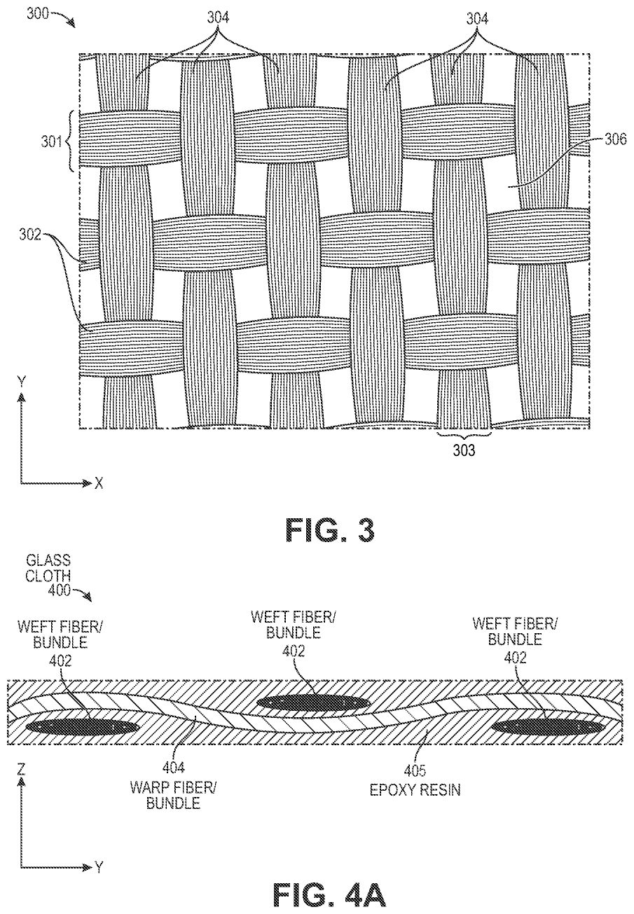

In contrast to conventional techniques for preventing warpage based on externally constraining the substrate, the internal laminate design can be modified to control warpage in the substrate. For example, warpage can be prevented or minimized by making design changes to the glass weave pattern of the glass cloth in the substrate. FIG. 3 illustrates a top-down view of an example of glass cloth 300 with a conventional two-way weave pattern. Typically, glass fabric is woven in a two-way weave pattern where the glass fibers are oriented in the horizontal and vertical direction to create a grid like structure. These patterns are either sparsely or densely woven in the warp and weft directions, as shown in FIG. 3. The example in FIG. 3 illustrates warp fibers or bundles 303 that each include warp filaments 304 in the vertical or longitudinal direction weaved together with weft fibers or bundles 301 that each include weft filaments 302 in the horizontal or transverse direction. The warp fibers may also be referred to as warp ends or ends. The weft fibers may also be referred to as fill. The warp fibers 303 are passed over and under the weft fibers 301 to form the grid weave pattern in FIG. 3.

The glass cloth 300 can be formed to have varying densities. A lower density glass cloth includes fewer fibers per a given area than higher density glass cloths. A lower density glass cloth may have larger voids in the weave, such as the void 306 between adjacent warp fibers and between adjacent weft fibers. Higher density glass cloths may have smaller voids, or no voids, between adjacent glass fibers. One example of a glass cloth is 1078 glass cloth, which includes 54 weft fibers and 54 warp fibers per inch and which has a thickness of 0.040 mm (0.0017″). Another example of a glass cloth is the 3313 glass cloth, which has a tighter weave than the 1078 glass cloth. The 3313 glass cloth includes 61 warp fibers and 62 weft fibers per square inch and has a thickness of 0.081 mm (0.0033″). Glass cloth may include a variety of other densities and thicknesses depending on the size of the glass filaments, fibers, and the tightness of the weave.

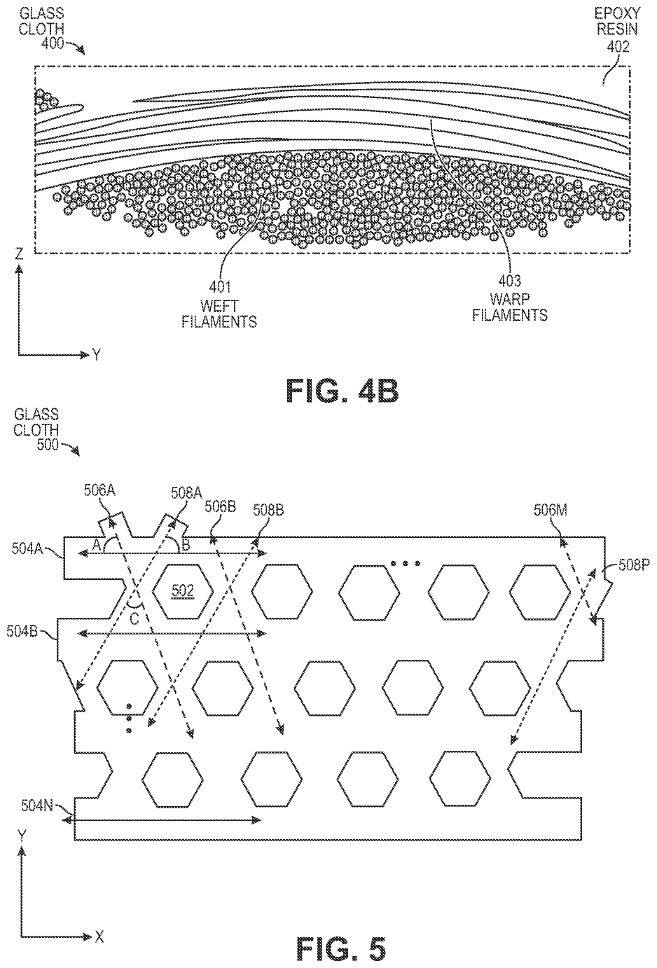

As mentioned above, once the glass cloth is woven, the glass cloth gets impregnated with epoxy and then cured through different stages to form core and prepreg laminates, which are then stacked together to form a substrate, such as the PCB 100 of FIG. 1. FIG. 4A is a cross-sectional view of an example of a portion of a glass cloth 400 impregnated with epoxy resin. The cross-sectional view slices through the weft fibers 402 along the Z-Y plane. In the view illustrated in FIG. 4A, a single warp fiber 404 is shown passing over and under the weft fibers 402 in an alternating pattern. The warp fibers adjacent to the warp fiber 404 (not shown in FIG. 4A) pass over and under the weft fibers 402 in the opposite pattern of the warp fiber 404, forming the grid or matrix weave of FIG. 3. An epoxy resin 405 surrounds the glass fibers of the glass cloth 400.

FIG. 4B is a close-up cross-sectional view of the glass cloth of FIG. 4A. FIG. 4B illustrates a cross-section of the individual glass filaments 401 of the fiber 402, and the individual glass filaments 403 of the fiber 404.

The density and direction of glass weave can have a significant impact on signal transmission, dielectric, and mechanical properties of the substrate. For example, the storage modulus of core with 3313 glass cloth is higher than core with 1078 glass cloth due to use of a dense glass weave, highlighting the impact of choosing a proper glass cloth pattern. Additionally, both these core materials exhibit significant directionality effects. For example, core materials that are cut along different directions exhibit a different storage modulus. In one example, a core with glass cloth having a two-way weave such as in FIG. 3 has the highest storage modulus when cut in the X-direction, followed by the Y-direction, and the lowest storage modulus in the XY-direction. The low storage modulus in the XY-direction is mainly due to an altered epoxy-to-glass ratio stemming from the two-directional weave pattern.

This uneven mechanical property distribution across the entire matrix can create instability in the composite behavior at higher temperatures. Additionally, square or rectangular BGA footprints typically have corners oriented along the XY-direction. Softer mechanical properties along corner (e.g., XY) directions create an easy path for out of plane deformation to occur, causing the corners to bend either up or down at elevated temperatures. This out of plane deformation of corners creates a warped BGA configuration.

In order to achieve uniform properties in all directions and minimize BGA footprint warpage, a three-way weave pattern in the glass cloth can be used instead of a standard two-way weave pattern. FIG. 5 illustrates an example of a portion of glass cloth 500 with a three-way (tri-axial) weave pattern. A tri-axial weave is a weave that includes at least three sets of glass fibers along different (e.g., non-parallel) axes. The glass cloth 500 of FIG. 5 includes three sets of glass fibers. Thus, the glass cloth includes a first plurality of parallel glass fibers 504A-504N, a second plurality of parallel glass fibers 506A-506M, and a third plurality of parallel glass fibers 508A-508P interwoven with one another. In one example, the first, second, and third pluralities of parallel glass fibers are interwoven with one another in a plane (the XY plane as illustrated in FIG. 5). As used herein, the fibers are considered to be interwoven in a plane if they are approximately in a plane, even if there is some deviation from the plane (e.g., due to fibers being woven over or other fibers). The first plurality of glass fibers 504A-504N could be referred to as a set of weft fibers, and the second and third pluralities of glass fibers 506A-506M and 508A-508P as two sets of warp fibers that are interwoven with the set of weft fibers.

The glass fibers in each set are parallel to one another, and at an angle with respect to the other sets of glass fibers. For example, the second plurality of parallel glass fibers 506A-506M crosses the first plurality of glass fibers 504A-504N at a first angle ‘A’. Similarly, the third plurality of parallel glass fibers 508A-508P crosses the first plurality of glass fibers 504A-504N at a second angle ‘B’. The third plurality of parallel glass fibers 508A-508P crosses the second plurality of glass fibers 506A-506M at a third angle ‘C’. In one example, the angles a and b between the warp and weft fibers are equal, and in a range of approximately 30-60 degrees. The angle ‘c’ between the two sets of warp fibers is greater than or equal to the angles ‘a’ and ‘b’. In one example, the first, second, and third pluralities of fibers all cross one another at the same angle. For example, the angles ‘a’, ‘b’, and ‘c’ are all 60 degrees. Thus, in one example, the tri-axial woven glass cloth 500 includes three sets of glass yarns: warp with ±bias and filling or weft, interlacing angularly with each other at an angle of 60°. In another example, the angles ‘a’ and ‘b’ are less than 60 degrees (e.g., 45 degrees), and the angle ‘c’ is greater than 60 degrees (e.g., 90 degrees). Different glass cloth examples may include the glass fibers interwoven at different angles A, B, and C than shown in FIG. 5. However, at least one set of glass fibers (e.g., 506A-506M) is at a non-orthogonal angle relative to another set of glass fibers (e.g., 504A-504N).

In one example, the pluralities of glass fibers cross one another to form voids between the glass fibers of the first, second, and third pluralities of parallel glass fibers. For example, the weave 500 includes a hexagonal void or gap 502 between adjacent fibers 504A and 504B, between adjacent fibers 506A and 506B, and between adjacent fibers 508A and 508B. Other weaves may include other shapes of voids (e.g., trigonal, or other shape), or no voids.

Thus, a tri-axial glass weave pattern can be accomplished by altering a biaxial weave pattern to address the biaxial weave pattern's inability to orient the fiber in off-axis direction that leads to composite materials with direction dependent mechanical properties. Different tri-axial weave patterns can be formed with large or small open gaps depending on the density of the weave. In one example, utilizing a three-way weave pattern such as in FIG. 5 creates a hexagonal structure in the weave pattern encompassing maximum area for efficient signal routing with the least perimeter. This not only leads to significant space savings but also helps in generating high uniform strength in all direction thereby providing warpage benefits. Additionally, having a hexagonal or trigonal glass weave structure may also provide controlled heat loss (e.g., due to increased glass content/unit area) and aid in improved signal transmission and dielectric properties of the material. Typically, transmission losses are kept low by orienting signals along the cross weave bundles. Having a multi weave pattern (e.g., a weave with multiple cross over points) may be advantageous in reducing transmission losses.

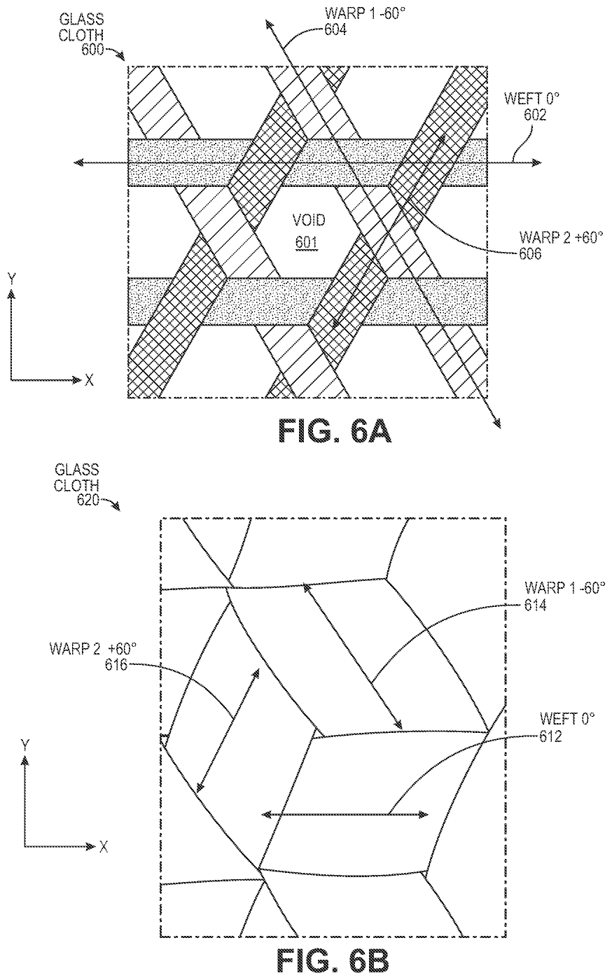

FIG. 6A is a close-up top-down view of an example of a glass cloth 600 with a tri-axial weave. In the example illustrated in FIG. 6A, the weft glass fibers 602 are at an angle of 0° relative to the X-axis. The warp 1 glass fibers 604 are at an angle of −60° relative to the weft fibers 602 and the X-axis. The warp 2 glass fibers 606 are at an angle of +60° relative to the weft fibers 602 and the X-axis. In the illustrated example, the warp 1 glass fibers 604 pass over the warp 2 glass fibers 606 and under the weft glass fibers 602. The warp 2 glass fibers 606 pass over the weft fibers 602. FIG. 6A illustrates one example of how the three sets of glass fibers can be interwoven, but other weaves are possible (e.g., the warp 1 fibers can pass under the weft fibers, and the warp 2 fibers can pass over the weft fibers).

As mentioned above, various densities of weaves can be achieved by adjusting the spacing of the glass fibers. In the example illustrated in FIG. 6A, the three sets of glass fibers are sufficiently spaced to produce a hexagonal void in the weave. FIG. 6B is a close-up top-down view of another example of a glass cloth 620 with a tri-axial weave. Like FIG. 6A, the glass cloth 620 in FIG. 6B includes three sets of glass fibers (weft fibers 612, warp 1 fibers 614, and warp 2 fibers 616). However, unlike FIG. 6A, the glass cloth 620 is tightly woven so that a gap is absent between parallel fibers.

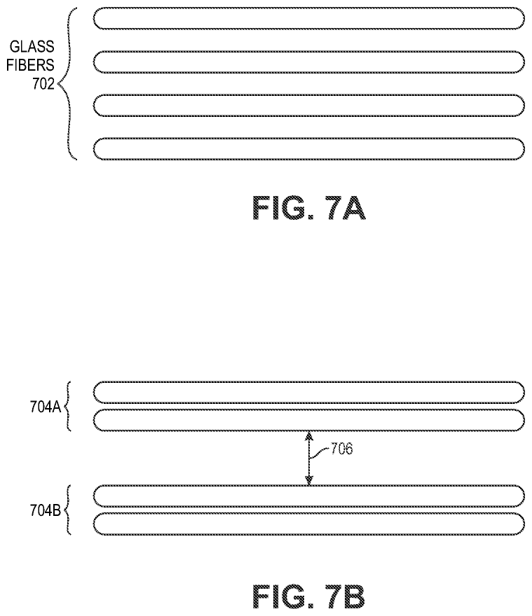

Although FIGS. 6A and 6B show examples in which the glass fibers are evenly spaced (e.g., the spacing between a given two adjacent parallel fibers is approximately equal), other weaves may include different spacing between glass fibers. FIG. 7A illustrates an example of glass fibers 702 that are evenly spaced. In one example, the glass fibers 702 of FIG. 7A may represent one or more of the glass fibers described herein. In one example, to form a tight weave with little or no openings, the spacing between adjacent glass fibers is approximately equal to the diameter of the glass fibers. In other denser weaves, there may be little or no spacing between adjacent glass fibers. In one such example, the weave may be formed with pairs of closely-spaced glass fibers. FIG. 7B illustrates an example of pairs 704A and 704B of closely-spaced glass fibers. In the example illustrated in FIG. 7B, the glass fibers in each pair 704A and 704B have little or no gap between them, but there is a larger gap 706 between the pairs 704A and 704B. In one example, the pairs 704A and 704B of glass fibers may represent one or more of the glass fibers described herein. Other spacing of glass fibers are also possible.

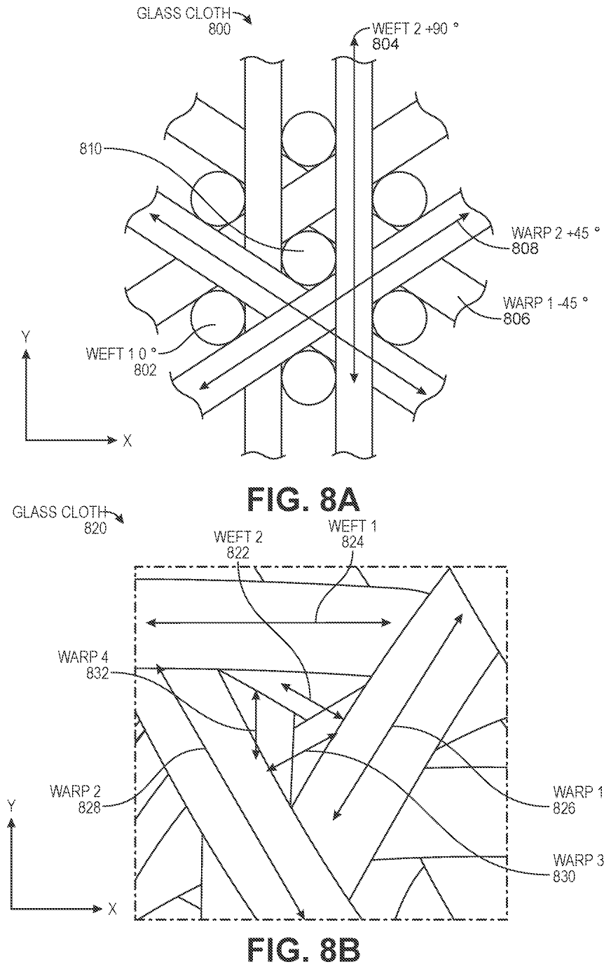

FIG. 8A illustrates an example of a glass cloth 800 with a tetra-axial weave. A tetra-axial weave is a weave that includes at least four sets of glass fibers along different (e.g., non-parallel) axes. In one example, the tetra-axial glass fabric 800 includes four sets of glass fibers: two sets of warp fibers 806 and 808 with ±bias and two sets of weft glass fibers 802 and 804 arranged in a tetra-axial woven glass fabric network. In one example, the tetra-axial glass fabric weave construction keeps the warp and weft direction weave patterns (with weft 804 and warp 806 and 808) in a plane that is perpendicular to the weft fibers 802. Thus, in the illustrated example, four pluralities of glass fibers are interwoven to form the cloth glass weave 800: a first plurality of parallel glass fibers 804, a second plurality of parallel glass fibers 806, and a third plurality of parallel glass fibers 808 interwoven with one another in a plane (e.g., the XY-plane). A fourth plurality of glass fibers 802 are orthogonally interwoven with the first, second, and third pluralities of parallel glass fibers. In the example of FIG. 8A, the fourth plurality of glass fibers 802 run in the direction in and out of the page. In one example, the fourth plurality of parallel glass fibers 802 is interwoven in the spaces (e.g., hexagonal space 810) between adjacent parallel glass fibers of the first, second, and third pluralities of parallel glass fibers.

The pluralities of glass fibers of FIG. 8A may be interwoven at particular angles (e.g., to achieve a hexagonal pattern, a trigonal pattern, or other tri-axial pattern). For example, the warp 1 and 2 glass fibers 806 and 808 can cross the weft 2 glass fibers 804 at angle in a range of 30-60 degrees. In the example illustrated in FIG. 8A, the warp 1 glass fibers 806 include a plurality of glass fibers at a −45° angle with respect to the weft 2 fibers 804 and the Y-axis. The warp 2 glass fibers 808 include a plurality of glass fibers at a +45° angle with respect to the weft 2 fibers 804 and the Y-axis. The weft 1 fibers 802 are perpendicular to the weft 2 fibers 804, the warp 1 fibers 806, and the warp 2 fibers 808. However, a glass cloth with a tetra-axial weave pattern may include glass fibers at other angles with respect to one another. In one such example, the warp 1 806, warp 2 808, and weft 2 804 are at 60° angles with respect to one another. In one example, the resulting glass weave fabric would have higher stability and exhibit isotropic properties in both principal and bias directions.

FIG. 8B is a close-up top-down view of an example of a glass cloth 820 with two sets of tri-axial weaves. In the example of FIG. 8B, the weave includes one set of tri-axial weaves (weft 1 824, warp 1 826, and warp 2 828) and a second set of tri-axial weaves (weft 2 822, warp 3 830, and warp 4 832) rotated with respect to one another. In the example of FIG. 8B, the first set of tri-axial weaves is more loosely woven to produce a trigonal void between the glass fibers. The second set of tri-axial weaves is more tightly woven within the voids of the first tri-axial weave. In the illustrated example, there are six glass fibers along different axes (e.g., one glass fiber every 30 degrees). Thus, the example glass cloth 820 includes two sets of 3-fold symmetric weaves rotated so that each set bisect the angles of the other set. Other numbers of glass fibers may also be interwoven to form a glass cloth with at least one subset of fibers having three-fold symmetry (e.g., 12 fibers, 15 fibers, or another number of glass fibers).

Although some examples refer to specific directions (e.g., horizontal and vertical) or specific degrees, these examples are for ease of understanding and are not intended to limit the invention as claimed below. It will be understood that the glass cloths described herein can include glass fibers interwoven in different directions and at different angles as long as there are at least three sets of glass fibers interwoven such that at least one set of glass fibers is at a degree less than 90 degrees relative to another set of glass fibers.

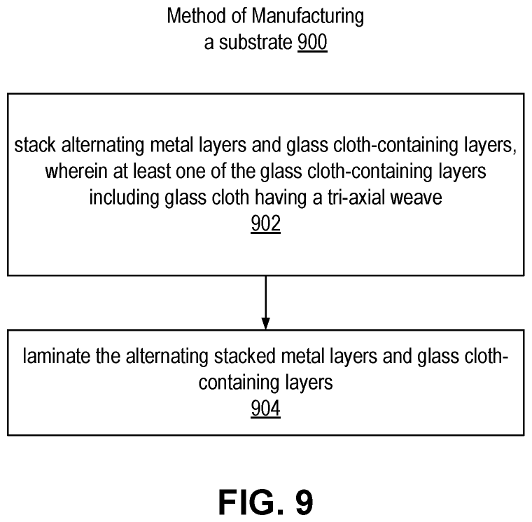

FIG. 9 is a flow diagram of a method 900 of an example of manufacturing a substrate including glass cloth (e.g., such as the PCB 100 of FIG. 1, or other substrate). The method 900 begins with stacking alternating metal layers and glass-cloth containing layers, at block 902. Stacking the layers may include, for example, copper layers, prepreg layers, and core layers such that each copper layer is separated by an insulating core layer or a prepreg layer. The prepreg and core layers may include a glass cloth with a tri-axial or tetra-axial weave as described herein. In one example, the manufacturing process for a tri-axial glass weave involves interlacing a weft glass yarn to a ±bias warp biaxial weave network created through vertical feed of multiple glass fabric beams arranged on a horizontally disposed rotating creel.

The method then involves laminating the alternating stacked metal layers and glass cloth-containing layers, at block 904. According to one example, laminating the stack involves applying heat and/or pressure, which fully cures the prepreg layers.

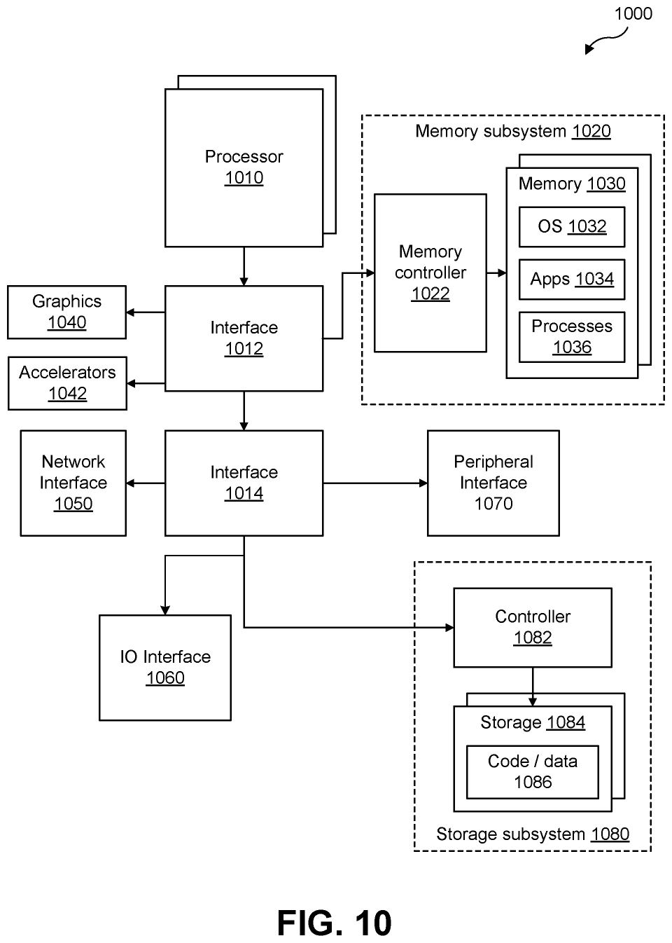

FIG. 10 depicts a compute platform 1000 such as a server or similar computing system in which techniques described herein may be implemented. Compute platform 1000 includes one or more processors 1010, which provides processing, operation management, and execution of instructions for compute platform 1000. Processor 1010 can include any type of microprocessor, central processing unit (CPU), graphics processing unit (GPU), processing core, multi-core processor or other processing hardware to provide processing for compute platform 1000, or a combination of processors. Processor 1010 controls the overall operation of compute platform 1000, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In some examples, processing may be split between a CPU and a GPU. For example, it is common to implement TensorFlow on compute platforms including a CPU and a GPU. In some examples, the CPU and GPU are separate components. In other embodiments, a CPU and GPU may be implemented in a System on a Chip (SoC) or in a multi-chip module or the like.

In one example, compute platform 1000 includes interface 1012 coupled to processor 1010, which can represent a higher speed interface or a high throughput interface for system components that needs higher bandwidth connections, such as memory subsystem 1020 or optional graphics interface components 1040, or optional accelerators 1042. Interface 1012 represents an interface circuit, which can be a standalone component or integrated onto a processor die. Where present, graphics interface 1040 interfaces to graphics components for providing a visual display to a user of compute platform 1000. In one example, graphics interface 1040 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 1040 generates a display based on data stored in memory 1030 or based on operations executed by processor 1010 or both. In one example, graphics interface 1040 generates a display based on data stored in memory 1030 or based on operations executed by processor 1010 or both.

In some examples, accelerators 1042 can be a fixed function offload engine that can be accessed or used by a processor 1010. For example, an accelerator among accelerators 1042 can provide data compression capability, cryptography services such as public key encryption (PKE), cipher, hash/authentication capabilities, decryption, or other capabilities or services. In some cases, accelerators 1042 can be integrated into a CPU socket (e.g., a connector to a motherboard or circuit board that includes a CPU and provides an electrical interface with the CPU). For example, accelerators 1042 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 1042 can provide multiple neural networks, CPUs, processor cores, general purpose graphics processing units, or graphics processing units can be made available for use by AI or ML models.

Memory subsystem 1020 represents the main memory of compute platform 1000 and provides storage for code to be executed by processor 1010, or data values to be used in executing a routine. Memory subsystem 1020 can include one or more memory devices 1030 such as read-only memory (ROM), flash memory, one or more varieties of random access memory (RAM) such as DRAM, or other memory devices, or a combination of such devices. Memory 1030 stores and hosts, among other things, operating system (OS) 1032 to provide a software platform for execution of instructions in compute platform 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for compute platform 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010.

While not specifically illustrated, it will be understood that compute platform 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, compute platform 1000 includes interface 1014, which can be coupled to interface 1012. In one example, interface 1014 represents an interface circuit, which can include standalone components and integrated circuitry. In one example, multiple user interface components or peripheral components, or both, couple to interface 1014. Network interface 1050 provides compute platform 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can transmit data to a device that is in the same data center or rack or a remote device, which can include sending data stored in memory. Network interface 1050 can receive data from a remote device, which can include storing received data into memory. Various embodiments can be used in connection with network interface 1050, processor 1010, and memory subsystem 1020.

In one example, compute platform 1000 includes one or more IO interface(s) 1060. IO interface 1060 can include one or more interface components through which a user interacts with compute platform 1000 (e.g., audio, alphanumeric, tactile/touch, or other interfacing). Peripheral interface 1070 can include any hardware interface not specifically mentioned above. Peripherals refer generally to devices that connect dependently to compute platform 1000. A dependent connection is one where compute platform 1000 provides the software platform or hardware platform or both on which operation executes, and with which a user interacts.

In one example, compute platform 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, or optical based disks, or a combination. Storage 1084 holds code or instructions and data 1086 in a persistent state (i.e., the value is retained despite interruption of power to compute platform 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to compute platform 1000). In one example, storage subsystem 1080 includes controller 1082 to interface with storage 1084. In one example, controller 1082 is a physical part of interface 1014 or processor 1010 or can include circuits or logic in both processor 1010 and interface 1014.

Volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein can be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013, DDR5 (DDR version 5), LPDDR5, HBM2E, HBM3, and HBM-PIM, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

In an example, compute platform 1000 can be implemented using interconnected compute sleds of processors, memories, storages, network interfaces, and other components. High speed interconnects can be used such as: Ethernet (IEEE 802.3), remote direct memory access (RDMA), InfiniBand, Internet Wide Area RDMA Protocol (iWARP), quick UDP Internet Connections (QUIC), RDMA over Converged Ethernet (RoCE), Peripheral Component Interconnect express (PCIe), Intel® QuickPath Interconnect (QPI), Intel® Ultra Path Interconnect (UPI), Intel® On-Chip System Fabric (IOSF), Omnipath, Compute Express Link (CXL), HyperTransport, high-speed fabric, NVLink, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof. Data can be copied or stored to virtualized storage nodes using a protocol such as NVMe over Fabrics (NVMe-oF) or NVMe.

In addition to systems with CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processor Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs and various forms of XPUs.

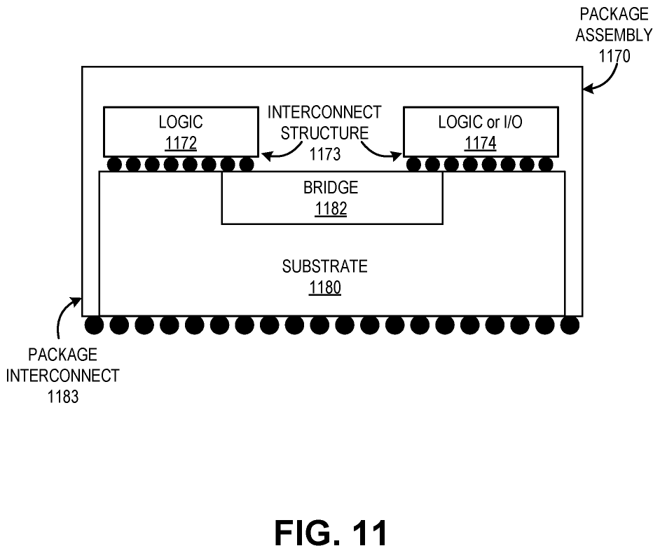

FIG. 11 illustrates a cross-section side view of an integrated circuit package assembly 1170. The package assembly 1170 (also referred to as a microelectronic assembly) illustrates an implementation of one or more processor or accelerator devices as described herein. The package assembly 1170 includes multiple units of hardware logic 1172, 1174 connected to a substrate 1180. The logic 1172, 1174 may be implemented at least partly in configurable logic or fixed-functionality logic hardware and can include one or more portions of any of the processor core(s), graphics processor(s), or other accelerator devices described herein. Each unit of logic 1172, 1174 can be implemented within a semiconductor die and coupled with the substrate 1180 via an interconnect structure 1173. The interconnect structure 1173 may be configured to route electrical signals between the logic 1172, 1174 and the substrate 1180, and can include interconnects such as, but not limited to bumps or pillars. The interconnect structure 1173 may be configured to route electrical signals such as, for example, input/output (I/O) signals and/or power or ground signals associated with the operation of the logic 1172, 1174. Optionally, the substrate 1180 may be an epoxy-based laminate substrate including a glass cloth as described herein. The substrate 1180 may also include other suitable types of substrates. The package assembly 1170 can be connected to other electrical devices via a package interconnect 1183. The package interconnect 1183 may be coupled to a surface of the substrate 1180 to route electrical signals to other electrical devices, such as a motherboard, other chipset, or multi-chip module.

The units of logic 1172, 1174 may be electrically coupled with a bridge 1182 that is configured to route electrical signals between the logic 1172, 1174. The bridge 1182 may be a dense interconnect structure that provides a route for electrical signals. The bridge 1182 may include a bridge substrate composed of glass or a suitable semiconductor material. Electrical routing features can be formed on the bridge substrate to provide a chip-to-chip connection between the logic 1172, 1174.

Although two units of logic 1172, 1174 and a bridge 1182 are illustrated, embodiments described herein may include more or fewer logic units on one or more dies. The one or more dies may be connected by zero or more bridges, as the bridge 1182 may be excluded when the logic is included on a single die. Alternatively, multiple dies or units of logic can be connected by one or more bridges. Additionally, multiple logic units, dies, and bridges can be connected together in other possible configurations, including three-dimensional configurations.

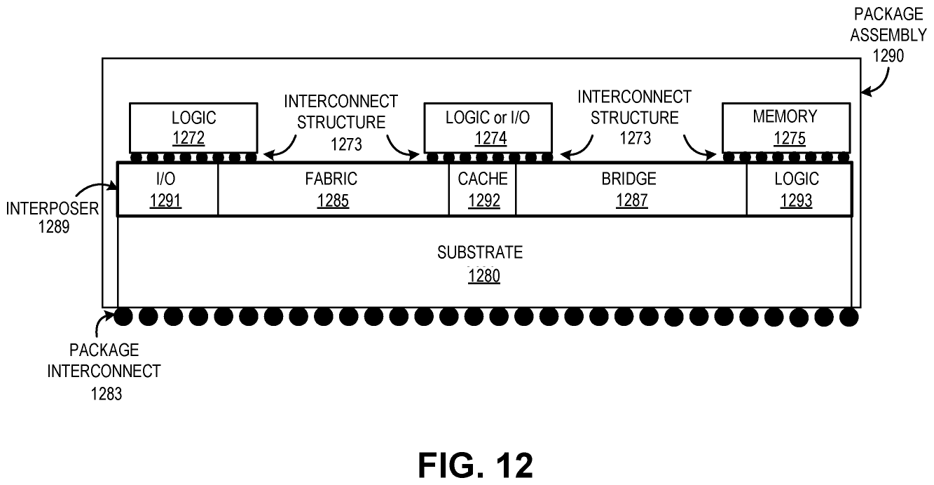

FIG. 12 illustrates a package assembly 1290 that includes multiple units of hardware logic chiplets connected to a substrate 1280 (e.g., base die). A graphics processing unit, parallel processor, and/or compute accelerator as described herein can be composed from diverse silicon chiplets that are separately manufactured. In this context, a chiplet is an at least partially packaged integrated circuit that includes distinct units of logic that can be assembled with other chiplets into a larger package. A diverse set of chiplets with different IP core logic can be assembled into a single device. Additionally the chiplets can be integrated into a base die or base chiplet using active interposer technology. The concepts described herein enable the interconnection and communication between the different forms of IP within the GPU. IP cores can be manufactured using different process technologies and composed during manufacturing, which avoids the complexity of converging multiple IPs, especially on a large SoC with several flavors IPs, to the same manufacturing process. Enabling the use of multiple process technologies improves the time to market and provides a cost-effective way to create multiple product SKUs. Additionally, the disaggregated IPs are more amenable to being power gated independently, components that are not in use on a given workload can be powered off, reducing overall power consumption.

In various embodiments a package assembly 1290 can include fewer or greater number of components and chiplets that are interconnected by a fabric 1285 or one or more bridges 1287. The chiplets within the package assembly 1290 may have a 2.5D arrangement using Chip-on-Wafer-on-Substrate stacking in which multiple dies are stacked side-by-side on a silicon interposer that includes through-silicon vias (TSVs) to couple the chiplets with the substrate 1280, which includes electrical connections to the package interconnect 1283.

In one embodiment, silicon interposer is an active interposer 1289 that includes embedded logic in addition to TSVs. In such embodiment, the chiplets within the package assembly 1290 are arranged using 3D face to face die stacking on top of the active interposer 1289. The active interposer 1289 can include hardware logic for I/O 1291, cache memory 1292, and other hardware logic 1293, in addition to interconnect fabric 1285 and a silicon bridge 1287. The fabric 1285 enables communication between the various logic chiplets 1272, 1274 and the logic 1291, 1293 within the active interposer 1289. The fabric 1285 may be an NoC interconnect or another form of packet switched fabric that switches data packets between components of the package assembly. For complex assemblies, the fabric 1285 may be a dedicated chiplet enables communication between the various hardware logic of the package assembly 1290.

Bridge structures 1287 within the active interposer 1289 may be used to facilitate a point to point interconnect between, for example, logic or I/O chiplets 1274 and memory chiplets 1275. In some implementations, bridge structures 1287 may also be embedded within the substrate 1280.

The hardware logic chiplets can include special purpose hardware logic chiplets 1272, logic or I/O chiplets 1274, and/or memory chiplets 1275. The hardware logic chiplets 1272 and logic or I/O chiplets 1274 may be implemented at least partly in configurable logic or fixed-functionality logic hardware and can include one or more portions of any of the processor core(s), graphics processor(s), parallel processors, or other accelerator devices described herein. The memory chiplets 1275 can be DRAM (e.g., GDDR, HBM) memory or cache (SRAM) memory. Cache memory 1292 within the active interposer 1289 (or substrate 1280) can act as a global cache for the package assembly 1290, part of a distributed global cache, or as a dedicated cache for the fabric 1285

Each chiplet can be fabricated as separate semiconductor die and coupled with a base die that is embedded within or coupled with the substrate 1280. The coupling with the substrate 1280 can be performed via an interconnect structure 1273. The interconnect structure 1273 may be configured to route electrical signals between the various chiplets and logic within the substrate 1280. The interconnect structure 1273 can include interconnects such as, but not limited to bumps or pillars. In some embodiments, the interconnect structure 1273 may be configured to route electrical signals such as, for example, input/output (I/O) signals and/or power or ground signals associated with the operation of the logic, I/O and memory chiplets. In one embodiment, an additional interconnect structure couples the active interposer 1289 with the substrate 1280.

The substrate 1280 may be an epoxy-based laminate substrate, however, it is not limited to that and the substrate 1280 may also include other suitable types of substrates including a glass cloth as described herein. The package assembly 1290 can be connected to other electrical devices via a package interconnect 1283. The package interconnect 1283 may be coupled to a surface of the substrate 1280 to route electrical signals to other electrical devices, such as a motherboard, other chipset, or multi-chip module.

A logic or I/O chiplet 1274 and a memory chiplet 1275 may be electrically coupled via a bridge 1287 that is configured to route electrical signals between the logic or I/O chiplet 1274 and a memory chiplet 1275. The bridge 1287 may be a dense interconnect structure that provides a route for electrical signals. The bridge 1287 may include a bridge substrate composed of glass or a suitable semiconductor material. Electrical routing features can be formed on the bridge substrate to provide a chip-to-chip connection between the logic or I/O chiplet 1274 and a memory chiplet 1275. The bridge 1287 may also be referred to as a silicon bridge or an interconnect bridge. For example, the bridge 1287 is an Embedded Multi-die Interconnect Bridge (EMIB). Alternatively, the bridge 1287 may simply be a direct connection from one chiplet to another chiplet.

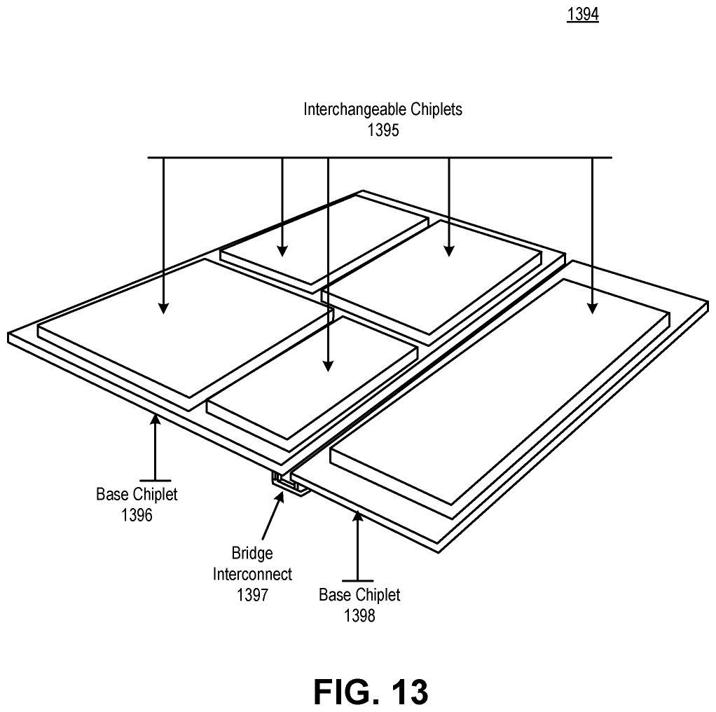

FIG. 13 illustrates a package assembly 1394 including interchangeable chiplets 1395, according to an embodiment. The interchangeable chiplets 1395 can be assembled into standardized slots on one or more base chiplets 1396, 1398. The base chiplets 1396, 1398 can be coupled via a bridge interconnect 1397, which can be similar to the other bridge interconnects described herein and may be, for example, an EMIB. Memory chiplets can also be connected to logic or I/O chiplets via a bridge interconnect. I/O and logic chiplets can communicate via an interconnect fabric. The base chiplets can each support one or more slots in a standardized format for one of logic or I/O or memory/cache.

SRAM and power delivery circuits may be fabricated into one or more of the base chiplets 1396, 1398, which can be fabricated using a different process technology relative to the interchangeable chiplets 1395 that are stacked on top of the base chiplets. For example, the base chiplets 1396, 1398 can be fabricated using a larger process technology, while the interchangeable chiplets can be manufactured using a smaller process technology. One or more of the interchangeable chiplets 1395 may be memory (e.g., DRAM) chiplets. Different memory densities can be selected for the package assembly 1394 based on the power, and/or performance targeted for the product that uses the package assembly 1394. Additionally, logic chiplets with a different number of type of functional units can be selected at time of assembly based on the power, and/or performance targeted for the product. Additionally, chiplets containing IP logic cores of differing types can be inserted into the interchangeable chiplet slots, enabling hybrid processor designs that can mix and match different technology IP blocks.

Examples of glass cloths for substrates, substrates, and microelectronic assemblies including glass cloth follow.

Example 1: A microelectronic assembly including: a substrate including one or more layers with glass cloth, at least one of the layers with glass cloth having a weave including: a first plurality of parallel glass fibers, a second plurality of parallel glass fibers, and a third plurality of parallel glass fibers interwoven with one another, wherein: the second plurality of parallel glass fibers crosses the first plurality of parallel glass fibers at a first angle, and the third plurality of parallel glass fibers crosses the first plurality of parallel glass fibers at a second angle and crosses the second plurality of parallel glass fibers at a third angle.

Example 2: The microelectronic assembly of example 1, wherein: the weave includes voids between adjacent parallel glass fibers of the first, second, and third pluralities of parallel glass fibers.

Example 3: The microelectronic assembly of any of examples 1 or 2, wherein the voids have a trigonal or hexagonal shape.

Example 4: The microelectronic assembly of any of examples 1-3, wherein: the second plurality of parallel glass fibers crosses the first plurality of parallel glass fibers at the first angle in a range of 30-60 degrees, the third plurality of parallel glass fibers crosses the first plurality of parallel glass fibers at the same first angle in the range of 30-60 degrees, and the third plurality of parallel glass fibers crosses the second plurality of parallel glass fibers at the third angle greater than or equal to the first angle.

Example 5: The microelectronic assembly of any of examples 1-4, wherein: the first, second, and third pluralities of parallel glass fibers all cross one another at the same angle.

Example 6: The microelectronic assembly of any of examples 1-5, wherein: the first, second, and third pluralities of parallel glass fibers all cross one another at a 60-degree angle.

Example 7: The microelectronic assembly of any of examples 1-6, wherein: the second and third pluralities of parallel glass fibers cross the first plurality of parallel glass fibers at a 45-degree angle.

Example 8: The microelectronic assembly of any of examples 1-7, wherein: the weave further includes a fourth plurality of parallel glass fibers orthogonally interwoven with the first, second, and third pluralities of parallel glass fibers.

Example 9: The microelectronic assembly of example 8, wherein: the fourth plurality of parallel glass fibers is interwoven in spaces between adjacent parallel glass fibers of the first, second, and third pluralities of parallel glass fibers.

Example 10: The microelectronic assembly of any of examples 1-9, wherein: the one or more layers with glass cloth include core or prepreg layers of the substrate.

Example 11: The microelectronic assembly of any of examples 1-10, further including: metal layers alternating with the one or more layers with glass cloth.

Example 12: The microelectronic assembly of any of examples 1-11, further including one or more of: conductive vias through the substrate, a semiconductor die mounted on the substrate, and a chiplet mounted on the substrate.

Example 13: A substrate for a microelectronic assembly, the substrate including: one or more layers of glass cloth, at least one of the layers of glass cloth having a weave including: a first plurality of parallel glass fibers, a second plurality of parallel glass fibers, and a third plurality of parallel glass fibers interwoven with one another, wherein: the second plurality of parallel glass fibers crosses the first plurality of parallel glass fibers at a first angle, and the third plurality of parallel glass fibers crosses the first plurality of parallel glass fibers at a second angle and crosses the second plurality of parallel glass fibers at a third angle.

Example 14: The substrate of example 13, wherein: the weave includes voids between adjacent parallel glass fibers of the first, second, and third pluralities of parallel glass fibers.

Example 15: The substrate of example 14, wherein: the voids have a trigonal or hexagonal shape.

Example 16: The substrate of any of examples 13-15, wherein: the second plurality of parallel glass fibers crosses the first plurality of parallel glass fibers at the first angle in a range of 30-60 degrees, the third plurality of parallel glass fibers crosses the first plurality of parallel glass fibers at the same first angle in the range of 30-60 degrees, and the third plurality of parallel glass fibers crosses the second plurality of parallel glass fibers at the third angle greater than or equal to the first angle.

Example 17: The substrate of any of examples 13-16, wherein: the first, second, and third pluralities of parallel glass fibers all cross one another at the same angle.

Example 18: The substrate of any of examples 13-17, wherein: the first, second, and third pluralities of parallel glass fibers all cross one another at a 60-degree angle.

Example 19: The substrate of any of examples 13-18, wherein: the second and third pluralities of parallel glass fibers cross the first plurality of parallel glass fibers at a 45-degree angle.

Example 20: The substrate of any of examples 13-19, wherein: the weave further includes a fourth plurality of parallel glass fibers orthogonally interwoven with the first, second, and third pluralities of parallel glass fibers.

Example 21: The substrate of any of examples 13-20, wherein: the fourth plurality of parallel glass fibers is interwoven in spaces between adjacent parallel glass fibers of the first, second, and third pluralities of parallel glass fibers.

Example 22: The substrate of any of examples 13-21, wherein: the one or more layers with glass cloth include core or prepreg layers.

Example 23: A glass cloth for a microelectronic substrate, the glass cloth including: a first plurality of parallel glass fibers, a second plurality of parallel glass fibers, and a third plurality of parallel glass fibers interwoven with one another, wherein the second plurality of parallel glass fibers crosses the first plurality of parallel glass fibers at a first angle, and wherein the third plurality of parallel glass fibers crosses the first plurality of parallel glass fibers at a second angle and crosses the second plurality of parallel glass fibers at a third angle.

20. The glass cloth of claim 19, wherein: the second plurality of parallel glass fibers crosses the first plurality of parallel glass fibers at the first angle in a range of 30-60 degrees, the third plurality of parallel glass fibers crosses the first plurality of parallel glass fibers at the same first angle in the range of 30-60 degrees, and the third plurality of parallel glass fibers crosses the second plurality of parallel glass fibers at the third angle greater than or equal to the first angle.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A microelectronic assembly comprising:
a substrate including one or more layers with glass cloth, at least one of the layers with glass cloth having a weave including:
a first plurality of parallel glass fibers, a second plurality of parallel glass fibers, and a third plurality of parallel glass fibers interwoven with one another, wherein:
the second plurality of parallel glass fibers crosses the first plurality of parallel glass fibers at a first angle, and
the third plurality of parallel glass fibers crosses the first plurality of parallel glass fibers at a second angle and crosses the second plurality of parallel glass fibers at a third angle.

2. The microelectronic assembly of claim 1, wherein:
the weave includes voids between adjacent parallel glass fibers of the first, second, and third pluralities of parallel glass fibers.

3. The microelectronic assembly of claim 2, wherein:
the voids have a trigonal or hexagonal shape.

4. The microelectronic assembly of claim 1, wherein:
the second plurality of parallel glass fibers crosses the first plurality of parallel glass fibers at the first angle in a range of 30-60 degrees;
the third plurality of parallel glass fibers crosses the first plurality of parallel glass fibers at the same first angle in the range of 30-60 degrees; and
the third plurality of parallel glass fibers crosses the second plurality of parallel glass fibers at the third angle greater than or equal to the first angle.

5. The microelectronic assembly of claim 1, wherein:
the first, second, and third pluralities of parallel glass fibers all cross one another at the same angle.

6. The microelectronic assembly of claim 1, wherein:
the first, second, and third pluralities of parallel glass fibers all cross one another at a 60-degree angle.

7. The microelectronic assembly of claim 1, wherein:
the second and third pluralities of parallel glass fibers cross the first plurality of parallel glass fibers at a 45-degree angle.

8. The microelectronic assembly of claim 1, wherein:
the weave further includes a fourth plurality of parallel glass fibers orthogonally interwoven with the first, second, and third pluralities of parallel glass fibers.

9. The microelectronic assembly of claim 8, wherein:
the fourth plurality of parallel glass fibers is interwoven in spaces between adjacent parallel glass fibers of the first, second, and third pluralities of parallel glass fibers.

10. The microelectronic assembly of claim 1, wherein:
the one or more layers with glass cloth include core or prepreg layers of the substrate.

11. The microelectronic assembly of claim 9, further comprising:
metal layers alternating with the one or more layers with glass cloth.

12. The microelectronic assembly of claim 1, further comprising one or more of:
conductive vias through the substrate, a semiconductor die mounted on the substrate, and a chiplet mounted on the substrate.

13. A substrate for a microelectronic assembly, the substrate comprising:
one or more layers of glass cloth, at least one of the layers of glass cloth having a weave including:
a first plurality of parallel glass fibers, a second plurality of parallel glass fibers, and a third plurality of parallel glass fibers interwoven with one another, wherein:
the second plurality of parallel glass fibers crosses the first plurality of parallel glass fibers at a first angle, and
the third plurality of parallel glass fibers crosses the first plurality of parallel glass fibers at a second angle and crosses the second plurality of parallel glass fibers at a third angle.

14. The substrate of claim 13, wherein:
the weave includes voids between adjacent parallel glass fibers of the first, second, and third pluralities of parallel glass fibers.

15. The substrate of claim 14, wherein:
the voids have a trigonal or hexagonal shape.

16. The substrate of claim 13, wherein:
the second plurality of parallel glass fibers crosses the first plurality of parallel glass fibers at the first angle in a range of 30-60 degrees;
the third plurality of parallel glass fibers crosses the first plurality of parallel glass fibers at the same first angle in the range of 30-60 degrees; and
the third plurality of parallel glass fibers crosses the second plurality of parallel glass fibers at the third angle greater than or equal to the first angle.

17. The substrate of claim 13, wherein:
the first, second, and third pluralities of parallel glass fibers all cross one another at the same angle.

18. The substrate of claim 13, wherein:
the first, second, and third pluralities of parallel glass fibers all cross one another at a 60-degree angle.

19. A glass cloth for a microelectronic substrate, the glass cloth comprising:
a first plurality of parallel glass fibers, a second plurality of parallel glass fibers, and a third plurality of parallel glass fibers interwoven with one another;
wherein the second plurality of parallel glass fibers crosses the first plurality of parallel glass fibers at a first angle; and
wherein the third plurality of parallel glass fibers crosses the first plurality of parallel glass fibers at a second angle and crosses the second plurality of parallel glass fibers at a third angle.

20. The glass cloth of claim 19, wherein:
the second plurality of parallel glass fibers crosses the first plurality of parallel glass fibers at the first angle in a range of 30-60 degrees;
the third plurality of parallel glass fibers crosses the first plurality of parallel glass fibers at the same first angle in the range of 30-60 degrees; and
the third plurality of parallel glass fibers crosses the second plurality of parallel glass fibers at the third angle greater than or equal to the first angle.
